(19) United States
(12) Patent Application Publication
(10) Pub. No.: US 2014/0029223 A1
(43) Pub. Date: Jan. 30, 2014

(54) CIRCUIT BOARD WITH REDUCED ADHESIVE OVERFLOW AND CIRCUIT STRUCTURE THEREOF

(71) Applicant: NISHO IMAGE TECH INC., New Taipei City (TW)

(72) Inventors: Tz-Liang Chang, New Taipei City (TW); Po-Hsiung Peng, New Taipei City (TW)

(73) Assignee: NISHO IMAGE TECH INC., New Taipei City (TW)

(21) Appl. No.: 13/676,985

(22) Filed: Nov. 14, 2012

(30) Foreign Application Priority Data
Jul. 25, 2012 (TW) 101214427

(51) Int. Cl. H05K 1/11; H05K 1/18

(52) U.S. Cl. CPC H05K 1/115; H05K 1/181
USPC 361/767; 174/266; 361/760

(57) ABSTRACT

A circuit board with reduced adhesive overflow includes a substrate and a conductive layer. The conductive layer is disposed on the substrate. The conductive layer includes a hole, a first placement area and a second placement area. The hole is used for forming a cavity with the substrate. The first placement area is used for the first electronic element to be fixedly connected onto the circuit board through the first contact surface. The second placement area is used for the second electronic element to be fixedly connected onto the circuit board through the second contact surface. An adjacent place of the first placement area and the second placement area and the hole are overlapped. The cavity is used to accommodate the conductive adhesive for fixedly connecting the first electronic element and the second electronic element.

### CROSS-REFERENCES TO RELATED APPLICATIONS

This non-provisional application claims priority under 35 U.S.C. §119(a) on Patent Application No. 101214427 filed in Taiwan, R.O.C. on Jul. 25, 2012, the entire contents of which are hereby incorporated by reference.

### BACKGROUND

1. Technical Field

The disclosure relates to a circuit board, and more particularly to a circuit board with reduced adhesive overflow and a circuit structure thereof.

2. Related Art

Because of the development of the integrated circuit manufacturing process and the improvement on the precision of the industrial control, electronic elements are more and more delicate and compact, so that a circuit board of the same area may hold a more and more complex circuit. However, in order to reduce the volume of an electronic product, circuits of the electronic product must be densely deployed on a circuit board, so electronic elements are considerably close.

FIG. 1 is a schematic sectional view of a circuit board 130 to which two electronic elements 110 are fixedly connected.

Please refer to FIG. 1, in order to quickly and precisely dispose the electronic elements 110 on the circuit board 130, conductive adhesive 120 including metal particles is generally used as a medium between the electronic elements 110 and the circuit board 130, so as to fix the electronic elements 110 and electrically connect the electronic elements 110 and a line of the circuit board 130. The circuit board 130 generally includes a dielectric layer 131 and a conductive layer 133 located thereon.

If the electronic elements 110 are disposed close to each other, it is easy to cause a capillary phenomenon. Due to the capillary phenomenon or the thermal expansion phenomenon, when the electronic elements 110 are fixedly connected, the conductive adhesive 120 located between the electronic elements 110 is excessive, which incurs an adhesive overflow phenomenon (namely, the conductive adhesive 120 between the electronic elements 110 overflows onto an upper end surface of the electronic elements 110). A surface of the electronic elements 110 is generally provided with a bonding pad 112, so as to couple a lead wire (not shown), onto a bonding pad (not shown), of the circuit board 130. If the conductive adhesive 120 contacts the bonding pad 112 on the surface of the electronic elements 110 due to the adhesive overflow phenomenon, a circuit connection error is caused. Therefore, the adhesive overflow phenomenon is one of main reasons resulting in decreased production yield.

### SUMMARY

In view of the problem, the disclosure provides a circuit board with reduced adhesive overflow and a circuit structure thereof, thereby solving the problem existing in the prior art that excessive conductive adhesive between electronic elements causes the adhesive overflow phenomenon.

An embodiment of the disclosure provides a circuit board with reduced adhesive overflow, which includes a substrate and a conductive layer. The conductive layer is disposed on the substrate.

The conductive layer includes a hole, a first placement area and a second placement area. The hole is used for forming a cavity with the substrate. The first placement area is approximately equal to a first contact surface of a first electronic element. The first placement area is used for the first electronic element to be fixedly connected onto the circuit board through the first contact surface. The second placement area is adjacent to the first placement area, and is approximately equal to a second contact surface of a second electronic element. The second placement area is used for the second electronic element to be fixedly connected onto the circuit board through the second contact surface.

An adjacent place of the first placement area and the second placement area and the hole are overlapped. The cavity is used to accommodate the conductive adhesive for fixedly connecting the first electronic element and the second electronic element.

An embodiment of the disclosure further provides a circuit structure with reduced adhesive overflow, which includes a substrate, a conductive layer, conductive adhesive, a first electronic element and a second electronic element.

The conductive layer is disposed on the substrate. The conductive adhesive is disposed on the conductive layer. The first electronic element and the second electronic element are disposed on the conductive adhesive.

The conductive layer includes a hole, for forming a cavity with the substrate. A part of the conductive adhesive is filled in the cavity. The second electronic element is adjacent to the first electronic element, in which an adjacent place of the first electronic element and the second electronic element is located on the cavity.

According to the circuit board with reduced adhesive overflow and the circuit structure thereof of the disclosure, the cavity located below the adjacent place of the electronic elements may accommodate surplus conductive adhesive, so as to avoid the excessively great height of the conductive adhesive between the electronic elements, thereby reducing occurrence of the adhesive overflow phenomenon.

### BRIEF DESCRIPTION OF THE DRAWINGS

The disclosure will become more fully understood from the detailed description given herein below for illustration only, and thus not limitative of the disclosure, where in:

FIG. 1 is a schematic sectional view of a circuit board to which two electronic elements are fixedly connected;

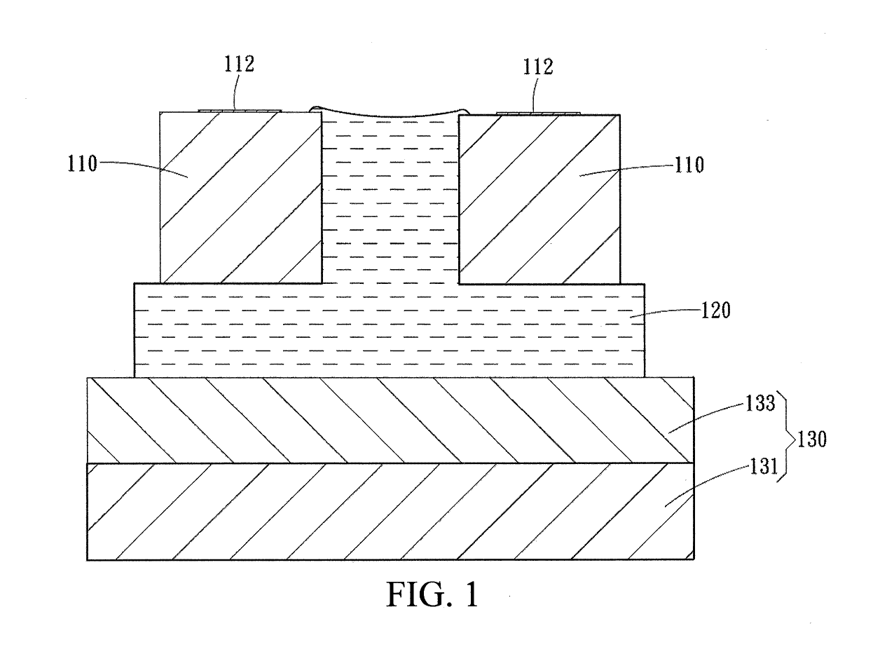

FIG. 2A is a top view of a circuit structure with reduced adhesive overflow according to a first embodiment of the disclosure;

FIG. 2B is an exploded view of the circuit structure with reduced adhesive overflow according to the first embodiment of the disclosure;

FIG. 2C is a side elevation view of the circuit structure with reduced adhesive overflow according to the first embodiment of the disclosure;

FIG. 2D is a sectional view along Line A-A shown in FIG. 2C of the circuit structure with reduced adhesive overflow according to the first embodiment of the disclosure;

FIG. 3 is a top view of a circuit structure with reduced adhesive overflow according to a second embodiment of the disclosure;

FIG. 4A is a top view of a circuit structure with reduced adhesive overflow according to a third embodiment of the disclosure;

FIG. 4B is an exploded view of the circuit structure with reduced adhesive overflow according to the third embodiment of the disclosure; and

FIG. 4C is a side elevation view of the circuit structure with reduced adhesive overflow according to the third embodiment of the disclosure.

### DETAILED DESCRIPTION

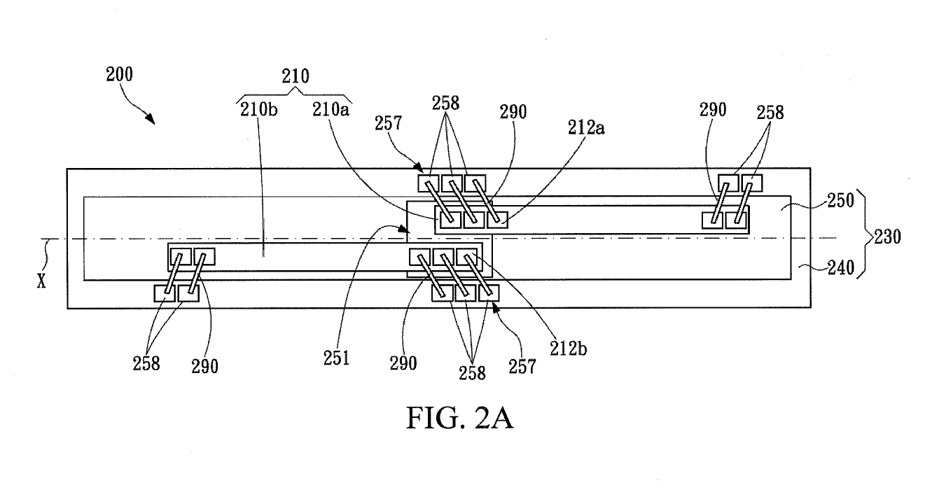

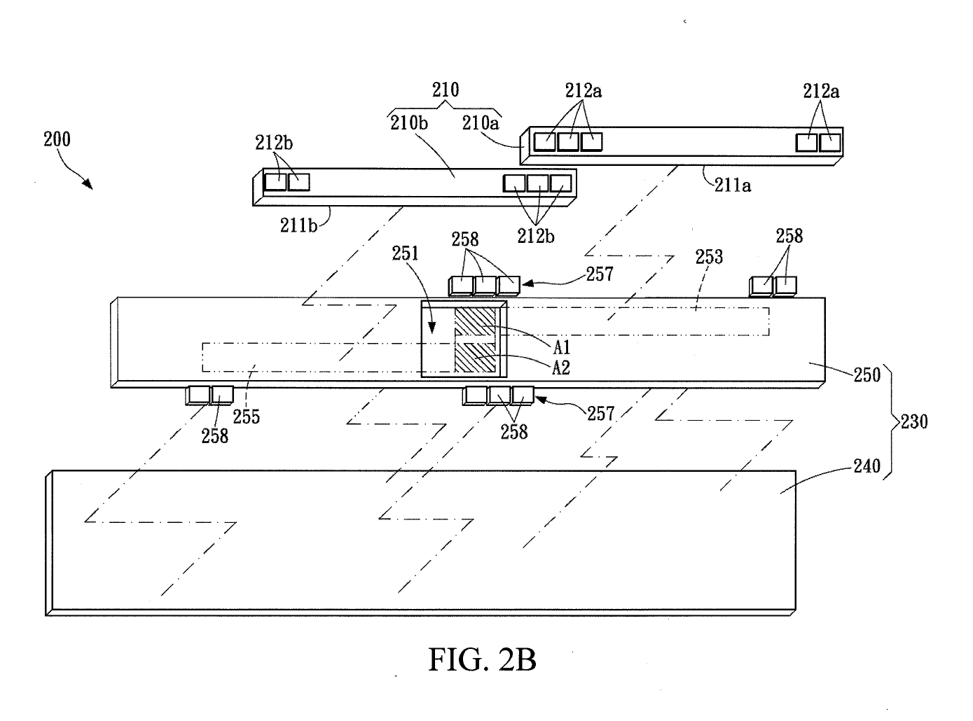

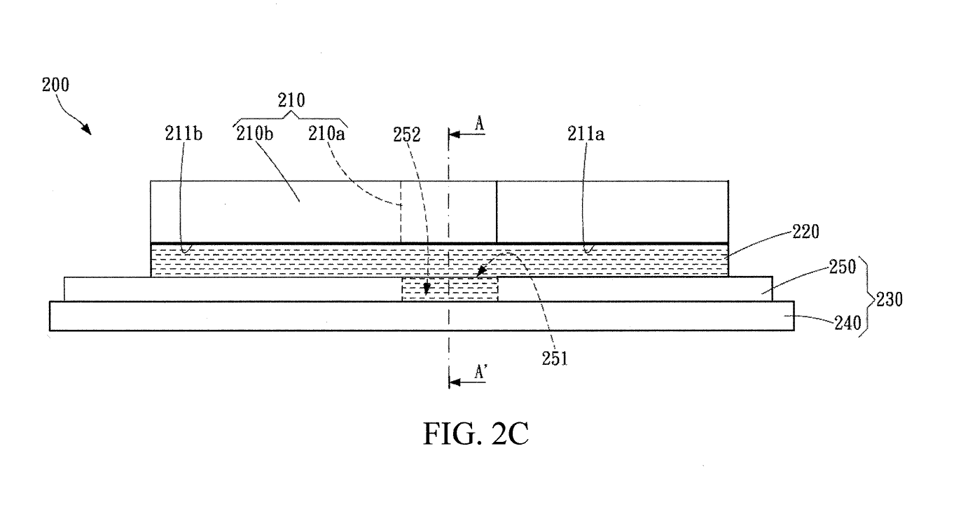

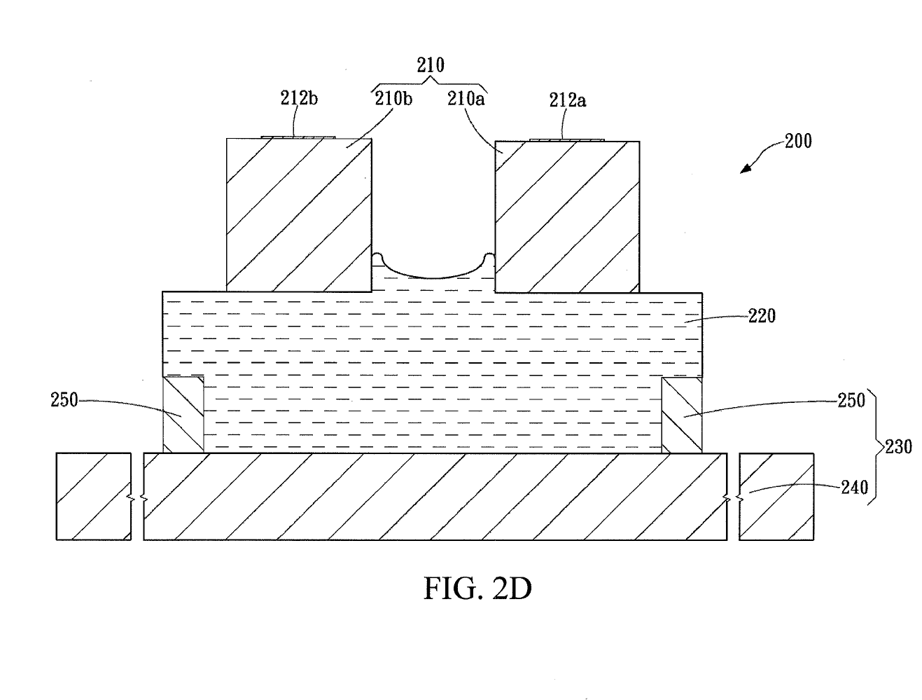

FIG. 2A is a top view of a circuit structure 200 with reduced adhesive overflow according to a first embodiment of the disclosure. FIG. 2B is an exploded view of the circuit structure 200 with reduced adhesive overflow according to the first embodiment of the disclosure. FIG. 2C is a side elevation view of the circuit structure 200 with reduced adhesive overflow according to the first embodiment of the disclosure. FIG. 2D is a sectional view along Line A-A shown in FIG. 2C of the circuit structure 200 with reduced adhesive overflow according to the first embodiment of the disclosure.

Please refer to FIG. 2A, FIG. 2B and FIG. 2C together, the circuit structure 200 with reduced adhesive overflow includes an electronic element 210, conductive adhesive 220 and a circuit board 230. The circuit board 230 includes a substrate 240 and a conductive layer 250.

Here, the electronic element 210 is illustrated by taking a first electronic element 210a and a second electronic element 210b as an example. Furthermore, in order to clearly present profiles of the first electronic element 210a, the second electronic element 210b and the circuit board 230, the conductive adhesive 220 and a lead wire 290 are not drawn in FIG. 2B.

The conductive layer 250 is disposed on the substrate 240. The conductive layer 250 includes a hole 251, a first placement area 253 and a second placement area 255.

The conductive layer 250 forms a cavity 252 with the substrate 240 through the hole 251. The cavity 252 is used to accommodate the conductive adhesive 220. Here, the conductive adhesive 220 is used to fixedly connect the first electronic element 210a and the second electronic element 210b onto the circuit board 230. That is to say, the conductive adhesive 220 is evenly coated on the conductive layer 250, and a part of the conductive adhesive 220 is filled in the cavity 252 because the bottom of the cavity 252 is lower than a surface of the conductive layer 250.

As shown in FIG. 2B, the first placement area 253 is approximately equal to a first contact surface 211a of the first electronic element 210a. The first placement area 253 is used for the first electronic element 210a to be fixedly connected onto the circuit board 230 through the first contact surface 211a. Here, the first contact surface 211 a is the lower surface of the first electronic element 210a, and is used to contact the conductive adhesive 220 so as to be fixedly connected onto the circuit board 230.

Similarly, the second placement area 255 is approximately equal to a second contact surface 211b of the second electronic element 210b. The second placement area 255 is used for the second electronic element 210b to be fixedly connected onto the circuit board 230 through the second contact surface 211b. Here, the second contact surface 211 b is the lower surface of the second electronic element 210b, and is used to contact the conductive adhesive 220 so as to be fixedly connected onto the circuit board 230.

Please refer to FIG. 2B and FIG. 2C together, in which an adjacent place of the first placement area 253 and the second placement area 255 and the hole 251 are overlapped. That is to say, the adjacent place of the first electronic element 210a and the second electronic element 210b is located on the cavity 252. The first electronic element 210a includes a first end and an opposite second end, and the second electronic element 210b also includes a first end and an opposite second end. For the first electronic element 210a and the second electronic element 210b, the first ends thereof are disposed adjacent to each other, and the second ends thereof are separately placed to be away from each other. In other words, opposite to respective first ends, the second end of the first electronic element 210a and the second end of the second electronic element 210b are respectively close to two opposite sides of the circuit board 230. Furthermore, both the first end of the first electronic element 210a and the first end of the second electronic element 210b are located on the cavity 252.

Therefore, the conductive adhesive 220 between the first electronic element 210a and the second electronic element 210b are partially filled in the cavity 252, so as to reduce the height of the conductive adhesive 220 between the first electronic element 210a and the second electronic element 210b, as shown in FIG. 2D.

Please refer to FIG. 2A, in which in some embodiments, the first placement area 253 and the second placement area 255 are separately placed at two sides of an axis X, and parts thereof are disposed side by side. Particularly, the first placement area 253 and the second placement area 255 are disposed along the axis X. That is to say, the first electronic element 210a and the second electronic element 210b are separately placed at two sides of the axis X, and parts thereof are disposed side by side (the first ends of the both are located above the hole 251 side by side). Particularly, the first electronic element 210a and the second electronic element 210b are disposed along the axis X. Therefore, when more than two placement areas exist, the electronic element 210 may be arranged along the axis X in a staggered manner. When the electronic element 210 is a light emitting chip including a plurality of light emitting diodes, the electronic element 210 arranged along the axis X may generate an even line light source.

Please refer to FIG. 2B, in which in some embodiments, the area of the hole 251 is greater than the sum of areas of side-by-side segments of both the first placement area 253 and the second placement area 255 (namely, the sum of areas of an area A1 and an area A2). In other words, the range of the hole 251 covers the side-by-side area of both the first placement area 253 and the second placement area 255 (namely, the area A1 and the area A2).

Please refer to FIG. 2A and FIG. 2B, in which in some embodiments, the first electronic element 210a and the second electronic element 210b may each include a bonding pad 212a and a bonding pad 212b. The bonding pad 212a may be disposed at the first end or/and the second end of the first electronic element 210a. The bonding pad 212b may be disposed at the first end or/and the second end of the second electronic element 210b.

The conductive layer 250 may further include a bonding pad portion 257. The bonding pad portion 257 is electrically insulated from the conductive layer 250 of the first placement area 253 and the second placement area 255, namely, the bonding pad portion 257 is electrically insulated from the conductive adhesive 220, and is used to be electrically connected to a bonding pad (namely, the bonding pad 212a or the bonding pad 212b), of one of the first electronic element 210a and the second electronic element 210b via the lead wire 290.

Here, the bonding pad portion 257 is formed of at least one bonding pad 258. The lead wire 290 may be made from metal materials such as gold, silver, titanium, copper, and palladium gold.

In some embodiments, the conductive adhesive 220 includes metal particles such as silver, aluminum, copper, nickel or a combination thereof The conductive adhesive 220 may be a photo-curable conductive adhesive or heat-curable conductive adhesive. The conductive adhesive 220 is cured by being irradiated by ultraviolet or being heated, so as to be fixedly connected to the electronic element 210.

In some embodiments, the substrate 240 is made from a dielectric material. The circuit board 230 may be a printed circuit board (PCB) of a single layer or multiple layers. When the circuit board 230 is a PCB of multiple layers, the substrate 240 is a dielectric substrate at the outermost layer, and the conductive layer 250 is disposed at an outer side of the substrate 240.

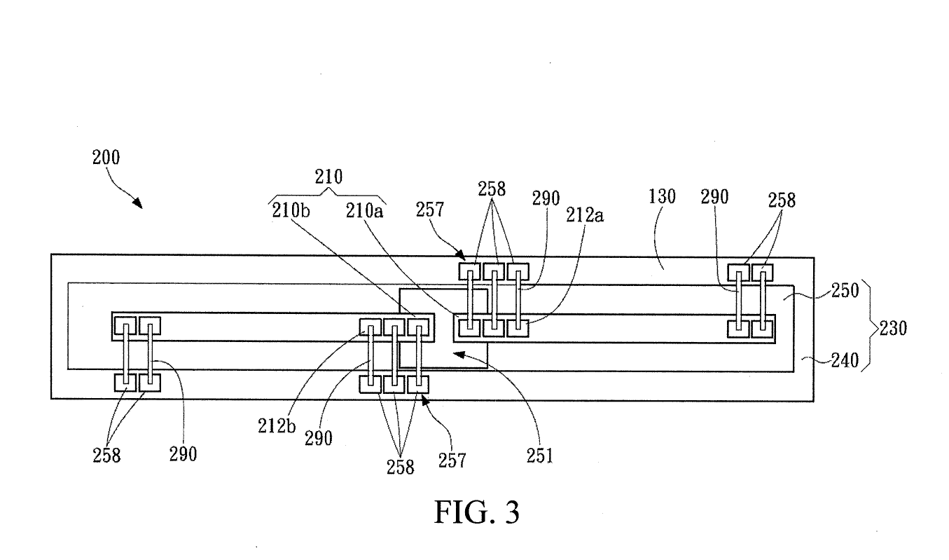

FIG. 3 is a top view of a circuit structure 200 with reduced adhesive overflow according to a second embodiment of the disclosure.

As shown in FIG. 3, in contrast with the first embodiment, a first electronic element 210a and a second electronic element 210b are disposed side by side. However, the range of a hole 251 still covers a part where the first electronic element 210a and the second electronic element 210b are adjacent to each other. That is to say, both the first end of the first electronic element 210a and the first end of the second electronic element 210b are located in the range of the hole 251.

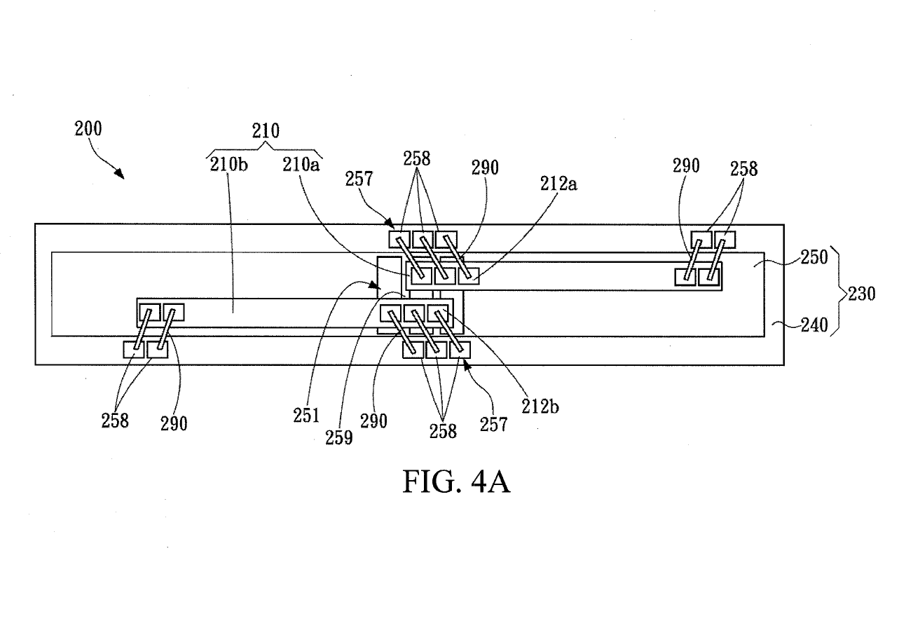

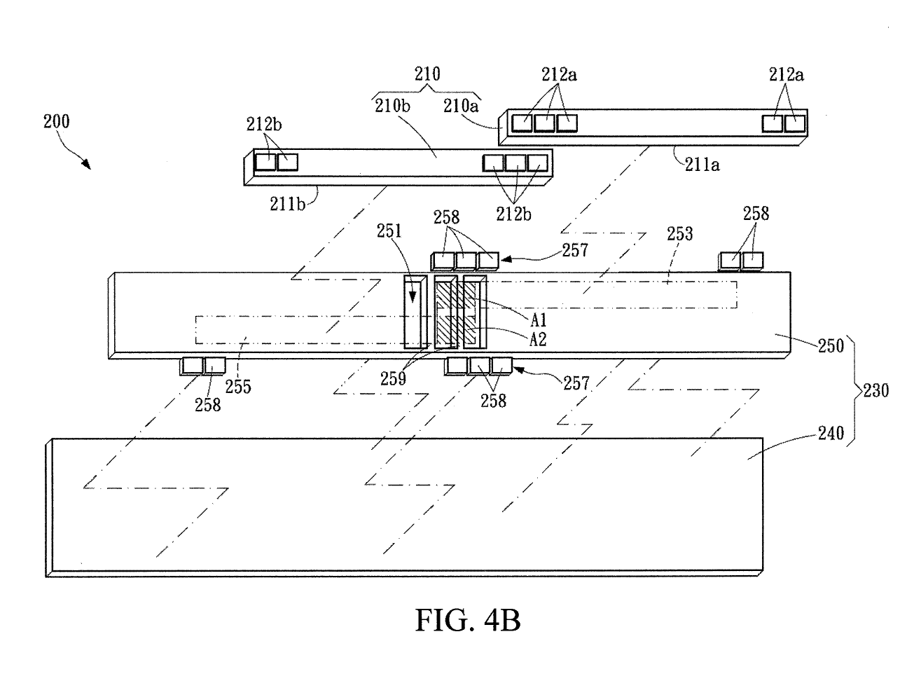

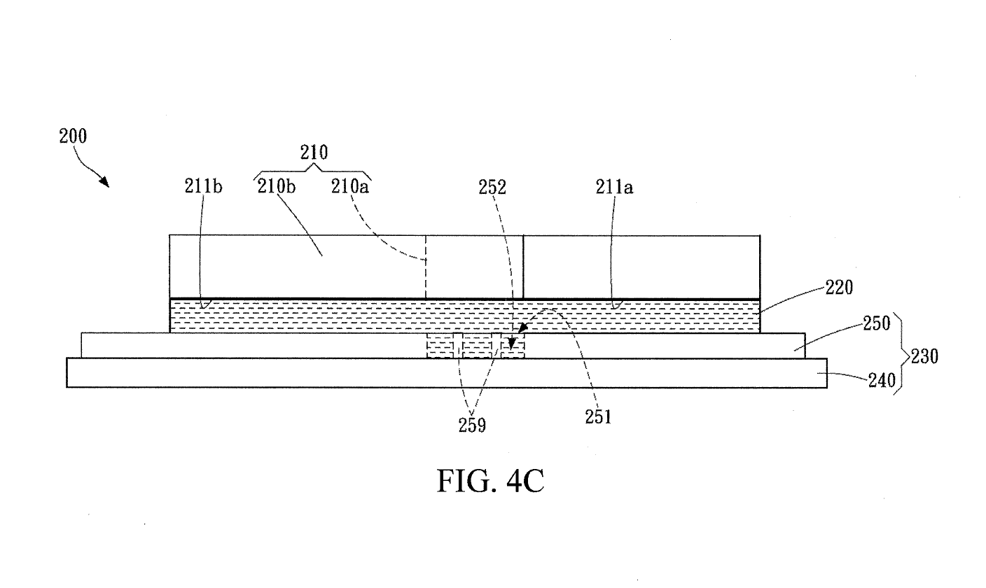

FIG. 4A is a top view of a circuit structure 200 with reduced adhesive overflow according to a third embodiment of the disclosure. FIG. 4B is an exploded view of the circuit structure 200 with reduced adhesive overflow according to the third embodiment of the disclosure. FIG. 4C is a side elevation view of the circuit structure 200 with reduced adhesive overflow according to the third embodiment of the disclosure.

Please refer to FIG. 4A, FIG. 4B and FIG. 4C in combination, in which compared with the circuit structure 200 of the first embodiment, a conductive layer 250 of the circuit structure 200 of this embodiment further includes a supporting portion 259 located in a hole 251. In addition to being coated on the conductive layer 250, conductive adhesive 220 further covers the supporting portion 259 and fully fills the cavity 252.

In some embodiments, a bonding pad 212a of a first electronic element 210a and a bonding pad 212b of a second electronic element 210b are disposed corresponding to the supporting portion 259. That is to say, when the first electronic element 210a is fixedly connected onto a circuit board 230 according to a first placement area 253, the bonding pad 212a of the first electronic element 210a is located above the supporting portion 259. Similarly, when the second electronic element 210b is fixedly connected onto the circuit board 230 according to a second placement area 255, the bonding pad 212b of the second electronic element 210b is located above the supporting portion 259. Thereby, the supporting strength of the conductive adhesive 220 in the cavity 252 may be improved, so as to avoid the thermal expansion phenomenon of the conductive adhesive 220 caused by the change of the ambient temperature, which makes the electronic element 210 offset, and the connecting strength of a lead wire 290 between the bonding pads 212a, 212b, and 258 may be improved.

Here, the profile of the supporting portion 259 shown in FIG. 4A and FIG. 4B is only exemplary, and the profile of the supporting portion 259 of the embodiment of the disclosure is not limited to the stripe shape. Persons skilled in the art may modify the profile of the supporting portion 259 based on actual situations such as the profile of the hole 251, the shape of the electronic element 210 and the location of the bonding pad.

Likewise, the profile of the hole 251 of the embodiment of the disclosure is not limited to the rectangle shown in FIG. 2A, FIG. 2B, FIG. 3, FIG. 4A and FIG. 4B either.

Furthermore, in order to clearly present profiles of the first electronic element 210a, the second electronic element 210b and the circuit board 230, the conductive adhesive 220 and the lead wire 290 are not drawn in FIG. 4B.

In some embodiments, the volume of the conductive adhesive 220 which the cavity 252 is capable of holding may be changed by adjusting the thickness of the conductive layer 250.

In some embodiments, the volume of the conductive adhesive 220 accommodated in the cavity 252 may be adjusted corresponding to the spacing distance of the electronic element 210. For example, when the conductive adhesive 200 of the same volume is coated, and if the spacing distance of the electronic element 210 is reduced, the thickness of the conductive layer 250 may be increased, so as to hold more conductive adhesive 220 in the cavity 252.

In some embodiments, the conductive layer 250 (including the hole 251, the first placement area 253, the second placement area 255, the bonding pad portion 257 and the supporting portion 259) is made by performing chemical etching or laser engraving on a conductive base material. Here, the conductive base material may be a material of metal such as copper, gold, and nickel or an alloy thereof, namely, the conductive layer 250 may be made from a material of metal such as copper, gold, and nickel or an alloy thereof.

In conclusion, according to the circuit board 230 with reduced adhesive overflow and the circuit structure 200 thereof of the disclosure, the cavity 252 located below the adjacent place of the electronic elements 210 may accommodate surplus conductive adhesive 220, so as to avoid the excessively great height of the conductive adhesive 220 between the electronic elements 210, and occurrence of the adhesive overflow phenomenon may be reduced. Furthermore, the supporting portion 259 disposed in the hole 251 may support the electronic element 210 with sufficient strength.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A circuit board with reduced adhesive overflow, comprising:
a substrate; and
a conductive layer, disposed on the substrate, wherein the conductive layer comprises:
a hole, for forming a cavity with the substrate;
a first placement area, approximately equal to a first contact surface of a first electronic element, wherein the first placement area is used for the first electronic element to be fixedly connected onto the circuit board through the first contact surface; and
a second placement area, adjacent to the first placement area, and approximately equal to a second contact surface of a second electronic element, wherein the second placement area is used for the second electronic element to be fixedly connected onto the circuit board through the second contact surface, an adjacent place of the first placement area and the second placement area is overlapped with the hole, and the cavity is used to accommodate conductive adhesive for fixedly connecting the first electronic element and the second electronic element.

2. The circuit board according to claim 1, wherein the first placement area and the second placement area are separately placed at two sides of an axis, and parts thereof are disposed side by side.

3. The circuit board according to claim 2, wherein the first placement area and the second placement area are disposed along the axis.

4. The circuit board according to claim 2, wherein the area of the hole is greater than the sum of areas of side-by-side segments of both the first placement area and the second placement area.

5. The circuit board according to claim 2, wherein the range of the hole covers side-by-side areas of both the first placement area and the second placement area.

6. The circuit board according to claim 1, wherein the conductive layer further comprises:
a supporting portion, located in the hole, wherein the conductive adhesive covers the supporting portion.

7. The circuit board according to claim 1, wherein the substrate is made from a dielectric material.

8. A circuit structure with reduced adhesive overflow, comprising:
a substrate;
a conductive layer, disposed on the substrate, wherein the conductive layer comprises a hole which forms a cavity with the substrate;
conductive adhesive, disposed on the conductive layer, wherein a part of the conductive adhesive is filled in the cavity;
a first electronic element, disposed on the conductive adhesive; and
a second electronic element, disposed on the conductive adhesive and being adjacent to the first electronic element, wherein an adjacent place of the first electronic element and the second electronic element is located on the cavity.

9. The circuit structure according to claim 8, wherein the first electronic element and the second electronic element are separately placed at two sides of an axis, and parts thereof are disposed side by side.

10. The circuit structure according to claim 9, wherein the first electronic element and the second electronic element are disposed along the axis.

11. The circuit structure according to claim 9, wherein the first electronic element comprises a first contact surface, the second electronic element comprises a second contact surface, and the first contact surface and the second contact surface are used to contact the conductive adhesive, the area of the hole is greater than the sum of areas of side-by-side segments of the first contact surface and the second contact surface corresponding to the first electronic element and the second electronic element.

12. The circuit structure according to claim 9, wherein the first electronic element comprises a first contact surface, the second electronic element comprises a second contact surface, the first contact surface and the second contact surface are used to contact the conductive adhesive, the range of the hole covers side-by-side areas of the first contact surface and the second contact surface corresponding to the first electronic element and the second electronic element.

13. The circuit structure according to claim 9, wherein the conductive layer further comprises:
a supporting portion, located in the hole, wherein the conductive adhesive covers the supporting portion.

14. The circuit structure according to claim 13, wherein the first electronic element and the second electronic element each comprise a bonding pad disposed corresponding to the supporting portion.

15. The circuit structure according to claim 14, wherein the conductive layer further comprises:
a bonding pad portion, electrically insulated from the conductive adhesive, and used to be electrically connected to the bonding pad of one of the first electronic element and the second electronic element via a lead wire.

16. The circuit structure according to claim 8, wherein the substrate is made from a dielectric material.
